(19) United States
(12) Patent Application Publication
(10) Pub. No.: US 2025/0006589 A1
(43) Pub. Date: Jan. 2, 2025

(54) FLUID-COOLED POWER MODULE

(71) Applicant: SEMICONDUCTOR COMPONENTS INDUSTRIES, LLC, Scottsdale, AZ (US)

(72) Inventor: John MOOKKEN, Scottsdale, AZ (US)

(73) Assignee: SEMICONDUCTOR COMPONENTS INDUSTRIES, LLC, Scottsdale, AZ (US)

(21) Appl. No.: 18/747,029

(22) Filed: Jun. 18, 2024

Related U.S. Application Data
(60) Provisional application No. 63/510,714, filed on Jun. 28, 2023.

(51) Int. Cl. H01L 23/473; H01L 23/373; H01L 23/495

(52) U.S. Cl. CPC H01L 23/4735; H01L 23/3737; H01L 23/49568

(57) ABSTRACT

A fluid-cooled power module is disclosed for cooling high power semiconductor devices. Semiconductor dies supported by a direct-bonded metal structure are attached to a cooling unit that circulates coolant from an inner chamber, through spray jets, to an outer chamber, so that coolant impinges onto a metal surface in thermal contact with the direct-bonded metal structure. Use of the cooling fluid provides more efficient and cost effective cooling than relying on a solid metal heat sink. The disclosed fluid-cooled power modules can reduce the cost and weight of heat dissipation for compatibility with aerospace applications.

### RELATED APPLICATION

This application claims the benefit of and priority to U.S. Provisional Application 63/510,714, filed on Jun. 28, 2023, entitled, “Power Module Housing,” which is incorporated herein by reference in its entirety.

### TECHNICAL FIELD

This description relates to assembling and packaging semiconductor device modules, semiconductor device assemblies, and semiconductor devices. More specifically, this description relates to cooling techniques for high power modules.

### SUMMARY

In some aspects, the techniques described herein relate to a module, including: a direct-bonded metal structure including a first conductive layer, a second conductive layer, and a non-conductive layer disposed between the first conductive layer and second conductive layer; a semiconductor die coupled to the first conductive layer of the direct-bonded metal structure; and a cooling unit coupled to the second conductive layer of the direct-bonded metal structure, the cooling unit including a fluid path such that a cooling fluid, when flowing through the fluid path, absorbs heat from at least a portion of the direct-bonded metal structure.

In some aspects, the techniques described herein relate to a module, wherein the cooling fluid impinges on a surface in thermal contact with the direct-bonded metal structure.

In some aspects, the techniques described herein relate to a module, wherein the direct-bonded metal structure includes a dielectric layer disposed between the first conductive layer and the second conductive layer, and the cooling fluid impinges on a surface in thermal contact with the second conductive layer.

In some aspects, the techniques described herein relate to a module, wherein the cooling unit includes a polymer-based material.

In some aspects, the techniques described herein relate to a module, wherein the cooling unit includes an inlet chamber and an outlet chamber that are separate from one another, and connected by cooling impingement jets.

In some aspects, the techniques described herein relate to a module, wherein the cooling unit is configured to direct flow of a cooling fluid from a module inlet, through a jet formed therein, toward the direct-bonded metal structure, and then away from the direct-bonded metal structure via the outlet chamber.

In some aspects, the techniques described herein relate to a module, wherein some of the cooling fluid that has passed through the jet is expelled from the cooling unit through a module outlet of the outlet chamber.

In some aspects, the techniques described herein relate to a module, wherein a temperature of the cooling fluid rises by up to between 2 degrees Celsius and 8 degrees Celsius while passing between the module inlet and the module outlet.

In some aspects, the techniques described herein relate to a module, wherein the module inlet and the module outlet include O-ring seals.

In some aspects, the techniques described herein relate to a module, further including a polymer lid over the semiconductor die.

In some aspects, the techniques described herein relate to a module, further including an epoxy between the polymer lid and the semiconductor die.

In some aspects, the techniques described herein relate to a module, wherein the cooling fluid includes ethylene glycol.

In some aspects, the techniques described herein relate to an apparatus, including: an inner chamber having an inlet; an outer chamber having an outlet, the outer chamber at least partially surrounding the inner chamber; and a channel formed in the inner chamber to direct a flow of a cooling fluid toward the outer chamber.

In some aspects, the techniques described herein relate to an apparatus, wherein the inner chamber and the outer chamber are formed from a polymer material by 3D printing.

In some aspects, the techniques described herein relate to an apparatus, wherein the inner chamber and the outer chamber are formed from a polymer material by injection molding.

In some aspects, the techniques described herein relate to an apparatus, wherein the channel pressurizes the cooling fluid to form an aerosol.

In some aspects, the techniques described herein relate to an apparatus, wherein the inlet is disposed below the inner chamber and the outlet is disposed below the outer chamber.

In some aspects, the techniques described herein relate to a method, including: directing a flow of a cooling fluid from an inlet to an inner chamber formed within a substrate supporting a semiconductor die such that heat is absorbed by the cooling fluid; directing the flow from the inner chamber through a plurality of openings to form a pressurized spray, causing the cooling fluid to impinge on a metal surface in thermal contact with a direct-bonded metal structure; receiving the cooling fluid in an outer chamber formed within the substrate; and ejecting the cooling fluid from the outer chamber through an outlet that is isolated from the inlet.

In some aspects, the techniques described herein relate to a method, wherein the cooling fluid is disposed below the direct-bonded metal structure.

In some aspects, the techniques described herein relate to a method, wherein the direct-bonded metal structure includes a first conductive layer, a second conductive layer, and a non-conductive layer disposed between the first conductive layer and second conductive layer.

### BRIEF DESCRIPTION OF THE DRAWINGS

FIG. 1 is a high level pictorial view of a fluid-cooled power module, according to some implementations of the present disclosure.

FIGS. 2-4 are cross-sectional views of isolated power modules, according to some implementations of the present disclosure.

FIG. 5A is a perspective view of an isolated module case, according to some implementations of the present disclosure.

FIG. 5B is a bottom perspective view of the isolated module case shown in FIG. 5A, according to some implementations of the present disclosure.

FIG. 5C is an exploded view of the isolated module case shown in FIG. 5A, according to some implementations of the present disclosure.

FIG. 6 is a perspective view of an interface between an isolated power module and a cooling jacket, according to some implementations of the present disclosure.

FIG. 7 is a cross-sectional view of an isolated module case, according to some implementations of the present disclosure.

FIG. 8 is an exploded view of an interface between an isolated power module and a base manifold, according to some implementations of the present disclosure.

FIG. 9 is a flow diagram illustrating a method of cooling a power module according to some implementations of the present disclosure.

Aspects of the present disclosure are best understood from the following detailed description when read with the accompanying figures. It is noted that, in accordance with common practice in the industry, various features are not necessarily drawn to scale. Dimensions of the various features may be arbitrarily increased or reduced for clarity of discussion. In the drawings, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings but are provided for context between related views. Also, not all like elements in the drawings are specifically referenced with a reference symbol when multiple instances of an element are illustrated.

### DETAILED DESCRIPTION

Semiconductor device assemblies, e.g., chip assemblies that include power semiconductor devices, can be implemented using multiple semiconductor dies, substrates (e.g., die attach pads (DAPs)), electrical interconnections, and a molding compound. The power transistors described herein can include, for example, insulated-gate bipolar transistors (IGBTs), power metal-oxide-semiconductor field effect transistors (MOSFETs), and so forth. Fast recovery diodes (FRDs) may be used in conjunction with power transistors. Electrical interconnections within a high-power semiconductor device module can include, for example, bond wires, conductive spacers, and conductive clips. A lead frame can be used to provide external electrical connections to the high-power semiconductor device module. A polymer molding compound can serve as an encapsulant to protect components of the device assembly. Some of the high-power chip assemblies described herein can operate at voltages in a range of, for example, about 200 V to about 800 V. Such high-power chip assemblies, encapsulated as semiconductor device modules, can be used as power converters in various applications, including electric vehicles (EVs), e.g., electric cars, airplanes, or drones, hybrid electric vehicles (HEVs), and industrial applications.

Within the power modules described herein, it is important to dissipate heat generated within power semiconductor devices to limit possible adverse effects of overheating such as dimensional variations, variable operating characteristics, and differential thermal expansion. Overheating can compromise reliability of the devices and also wastes power, thereby increasing operating costs. Ineffective cooling of semiconductor devices may impose limitations on the design of power chip assemblies by constraining permissible power density, circuit density, or system speed. When heat is dissipated from a source (e.g., a power module) to a sink (e.g., a heat sink) by conduction, successful heat transfer can depend on, for example, the direct contact area between the source and the heat sink.

In some power modules, chip assemblies are supported by a multilevel substrate, e.g., a direct-bonded metal (DBM) structure (which can be a directed bonded copper (DBC) substrate). The DBM structure can be used, in part, to facilitate cooling of high power semiconductor devices. The DBM structure can include a first conductive layer, a second conductive layer, and a non-conductive layer, e.g., a dielectric layer, made of an insulating material, e.g., a ceramic material, disposed between the first conductive layer and the second conductive layer. The first conductive layer (and/or the second conductive layer) can include, or can define, one or more electrical traces and/or connections. The second conductive layer, and/or the first conductive layer, can be, or can function as, a heat sink. In some implementations, the second conductive layer can be coupled to a heat sink for single-sided cooling.

In some implementations, multiple DBMs (e.g., two DBMs) can be used for double-sided cooling, or for cooling multiple arrays of high power chips. A heat sink for attachment to a DBM can be constructed as a metal base plate or metal fins, e.g., a “pin-fin” type heat sink, for accelerating heat dissipation by providing an increased metal surface area. However, at least one problem with such heat sinks is that they still may not dissipate heat fast enough. Also, a metal base plate can add undesirable weight and cost to the power module. In some implementations, the DBM structure can be referred to as a DBM substrate.

This disclosure relates to implementations of a direct cooling approach in which a cooling unit of a fluid-cooled power module includes (e.g., defines, forms) a chamber to include (e.g., contain, facilitate flow of) a cooling fluid. The cooling unit can be coupled to a DBM structure, with an intervening layer of a conductive bonding agent. In some implementations, the cooling fluid is contained in an inner chamber having an inlet (“inlet chamber”) while the cooling unit further includes an outer chamber having an outlet (“outlet chamber”), separate from the inlet, such that the two chambers are independent of one another. In some implementations, a channel connects the inlet to the outlet. In some implementations, jets formed in the inner chamber direct fluid flow through the channel toward the outer chamber. In some implementations, fluid from the inner chamber can be pressurized to form a spray used to cool a lower surface of the DBM. In some implementations, a radiator can be used to extract heat from fluid at the outlet so that the fluid can be re-circulated through the cooling unit.

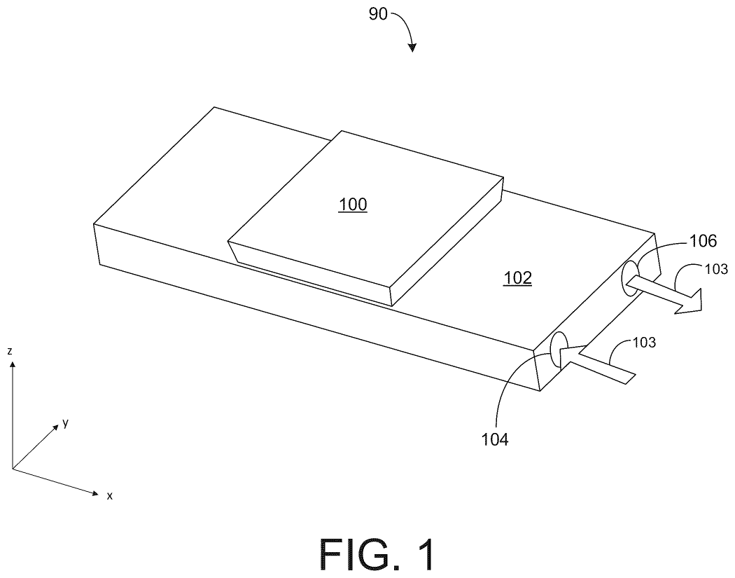

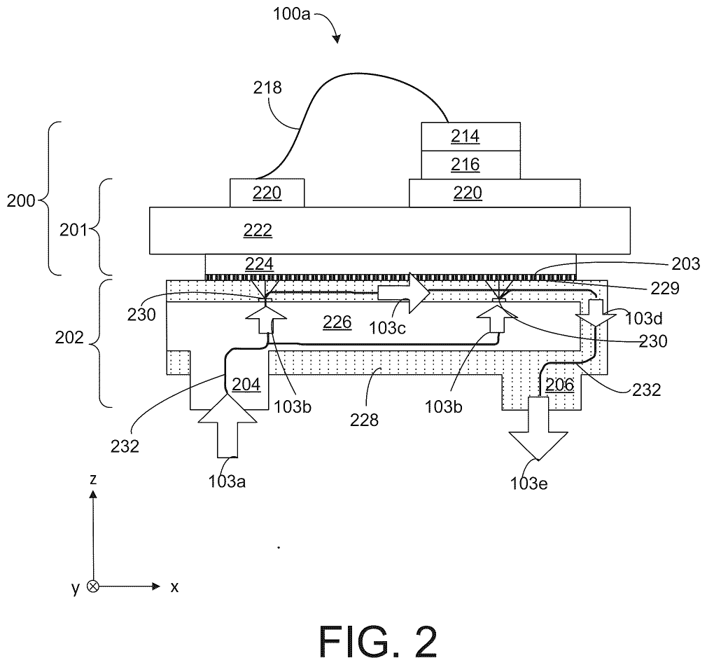

FIG. 1 is a high-level exterior perspective view of a fluid-cooled power module 90, in accordance with some implementations of the present disclosure. The fluid-cooled power module 90 includes an isolated power module 100 mounted on (e.g., attached to, coupled to) a cooling jacket 102. In some implementations, the isolated power module 100 is a high power module that generates heat when energized, e.g., during operation of one or more semiconductor chips within the isolated power module 100. In some implementations, the cooling jacket 102 can be made of cast aluminum. In some implementations, the cooling jacket 102 can be polymer-based. The cooling jacket 102 provides containment for a flow 103 of a cooling fluid, wherein the flow direction is indicated by arrows. An inlet 104 at one end of the cooling jacket 102 is shown in FIG. 1, through which the cooling fluid can flow into the cooling jacket 102 and from the cooling jacket 102 into the isolated power module 100 during operation. An outlet 106 at an opposite side of the cooling jacket 102 from the location of the inlet 104 is shown in FIG. 1, through which the cooling fluid can exit the cooling jacket 102 during operation. In some implementations as shown in FIGS. 2-10 and described below, the cooling fluid interacts with a heat sink internal to the isolated power module 100.

FIG. 2 is a cross-sectional view of a first example 100a of the isolated power module 100, in accordance with some implementations of the present disclosure. In the first example 100a, the isolated power module 100 includes a DBM assembly 200, or isolator, coupled to a heat dissipation assembly 202, e.g., a cooling unit, using a conductive bonding agent 203, so as to efficiently dissipate heat produced by the DBM assembly 200. The heat dissipation assembly 202 has a module inlet 204 and a module outlet 206 to direct the flow 103 of cooling fluid from the cooling jacket 102 toward the DBM assembly 200.

The DBM assembly 200 includes a multi-layer substrate, e.g., a DBM structure 201, supporting a single electronic component, e.g., a single chip or semiconductor die 214. The semiconductor die 214 can be attached to, e.g., mounted on, or coupled to, a top surface of the DBM structure 201 by a bonding agent 216, e.g., an epoxy, a solder, a silver (Ag) sintering material, and/or an adhesive. The semiconductor die 214, during high power operation, may generate heat and may cause heat accumulation within the isolated power module 100. The DBM structure 201 may serve as a heat spreader that provides single-sided cooling of the semiconductor die 214. In some implementations, the DBM structure 201 can radiate heat from both the back side and the front side, acting as a double-sided heat sink to dissipate heat produced by the isolated power module 100.

In some implementations, the semiconductor die 214 can include integrated circuits and/or discrete electronic components suitable for high power applications. In some implementations, the semiconductor die 214 can include for example, a controller and/or an insulated gate bipolar transistor (IGBT). The IGBT is a three-terminal device that includes an emitter, a gate, and a collector. In some implementations that include multiple semiconductor dies 214, such dies can include an IGBT, and a controller configured to control the IGBT. The controller can also serve as a protection device for the IGBT. For example, the controller can provide temperature protection and/or over-voltage protection for the IGBT. The controller can also limit the amount of current delivered to the IGBT. In some implementations, the controller can be configured to monitor the IGBT. In some implementations, other types of semiconductor dies, e.g., silicon MOSFETs, silicon carbide (SIC) MOSFETs, diodes, and so forth, can be used. In some implementations, a SiC MOSFET can be substituted for the IGBT. In some implementations, fast recovery diodes (FRDs) may be used in conjunction with power transistors.

The semiconductor die 214 can be fabricated on various types of semiconductor substrates, e.g., semiconductor wafers, for example, silicon (Si), silicon carbide (SiC), gallium (Ga), gallium nitride (GaN), aluminum gallium nitride (AlGaN), gallium arsenide (GaAs), aluminum gallium arsenide (AlGaAs), indium phosphide (InP), glass substrates, sapphire substrates, and so on. In general, any type of semiconductor die 214 can be fabricated on any type of substrate.

In some implementations, different semiconductor dies 214 can be fabricated on different substrates in a hybrid configuration. For example, a first die can be fabricated using a SiC substrate, while a second die can be fabricated using a silicon substrate. As a particular example, an IGBT can be fabricated on a SiC substrate, while a controller can be fabricated on a silicon substrate. In some implementations as described herein, multiple semiconductor dies 214 can be fabricated on the same substrate, e.g., on a SiC substrate, suitable for high power applications.

In some implementations, the DBM structure 201 can be a direct bond copper (DBC) type structure, a direct plating copper (DPC) type structure, or a direct bond aluminum (DBA) type structure. In some implementations, the DBM structure 201 is designed as a three-layer DBM structure that includes a non-conductive layer 222 disposed between, e.g. sandwiched between, a first conductive layer 220 and a second conductive layer 224. In some implementations, the non-conductive layer 222 serves as a thermal mass disposed between the first conductive layer 220 and the second conductive layer 224 to draw in and absorb heat. The non-conductive layer 222 may also provide electrical insulation between the first conductive layer 220 and the second conductive layer 224 of the DBM structure 201.

In some implementations, the first conductive layer 220 and/or the second conductive layer 224 can be, or can include, a metal layer (e.g., a copper layer, a copper alloy layer) that is formed on (e.g., bonded to, sputtered on, diffused onto to, heat-formed on) the non-conductive layer 222. The first conductive layer 220 can be coupled to a first side of the non-conductive layer 222, and the second conductive layer 224 can be coupled to a second side of the non-conductive layer 222. The first conductive layer 220 or the second conductive layer 224 can be referred to as an upper conductive layer, e.g., a top layer, or as a lower conductive layer, e.g., a bottom layer, depending on the orientation of the device. In some implementations, the non-conductive layer 222 can be a ceramic, e.g., silicon nitride (Si₃N₄) or aluminum oxide (Al₂O₃), Si₃N₄ being a significantly more expensive ceramic material than Al₂O₃. In some implementations, the DBM structure 201 has a thickness in a range of about 0.5 mm to about 3.0 mm.

In some implementations, the semiconductor die 214 can be mounted on (e.g., attached to, coupled to, adhered to) the DBM structure 201 by the bonding agent 216. The bonding agent 216 can include a solder or a sintering layer e.g., a conductive epoxy, a silver (Ag) or copper (Cu) sintering material, and/or an adhesive., e.g., an epoxy, a glue, or a tape such as a polyimide tape, or other type of conductive adhesive. In some implementations that include multiple semiconductor dies 214, first and second semiconductor dies 214 can be coupled to the first conductive layer 220 by two different bonding agents. For example, in some implementations, a first semiconductor die 214 can be attached to the first conductive layer 220 by sintering, while a second semiconductor die 214 is attached to the first conductive layer 220 using conductive polyimide tape.

In some implementations, the first conductive layer 220 can be patterned, e.g., by etching, to form a die attach that provides support for the semiconductor die 214. In some implementations, the first conductive layer 220 can be, or can include, a metal redistribution layer (RDL) pattern on which to mount (or couple) the semiconductor die 214 using a die attach (DA). The DA can be integral to, or attached to, the first conductive layer 220 of the DBM structure 201. In some implementations, the non-conductive layer 222 and/or the second conductive layer 224 of the DBM structure 201 can have a larger footprint than the die attach.

The isolated power module 100 can further include one or more wire bonds 218. The wire bond(s) 218 can electrically couple the semiconductor die 214 to the first conductive layer 220.

FIG. 2 further illustrates details of the heat dissipation assembly 202, in accordance with some implementations of the present disclosure. In particular, the heat dissipation assembly 202 includes components that implement a method of active cooling, e.g., jet impingement cooling, in which the heat dissipation assembly 202 can be equipped with an inlet chamber 226, an outlet chamber 228, and jets 230, e.g., cooling impingement jets (two shown) that provide a fluid path between the inlet chamber 226 and the outlet chamber 228. In some implementations, the outlet chamber 228 surrounds the inlet chamber 226. In some implementations, the inlet chamber 226 can be disposed between a first portion (e.g., top portion) of the outlet chamber 228 and a second portion e.g., a bottom portion, of the outlet chamber 228. In some implementations, the inlet chamber 226 and the outlet chamber 228 are both closed chambers, so that once fluid moves from the inlet chamber 226 to the outlet chamber 228 via the jets 230, the fluid cannot e.g., substantially cannot, return to the inlet chamber 226. That is, the jets 230 serve as uni-directional valves, preventing hot fluid in the outlet chamber 228 from mixing with cold fluid in the inlet chamber 226. In some implementations, the module inlet 204 is disposed below the inlet chamber 226 and the module outlet 206 is disposed below the outlet chamber 228.

In some implementations, one or more of the jets 230 can be, or can include, an opening. In some implementations, one or more of the jets 230 can have a tapered shape. In some implementations, one or more of the jets 230 can have a circular cross-sectional shape.

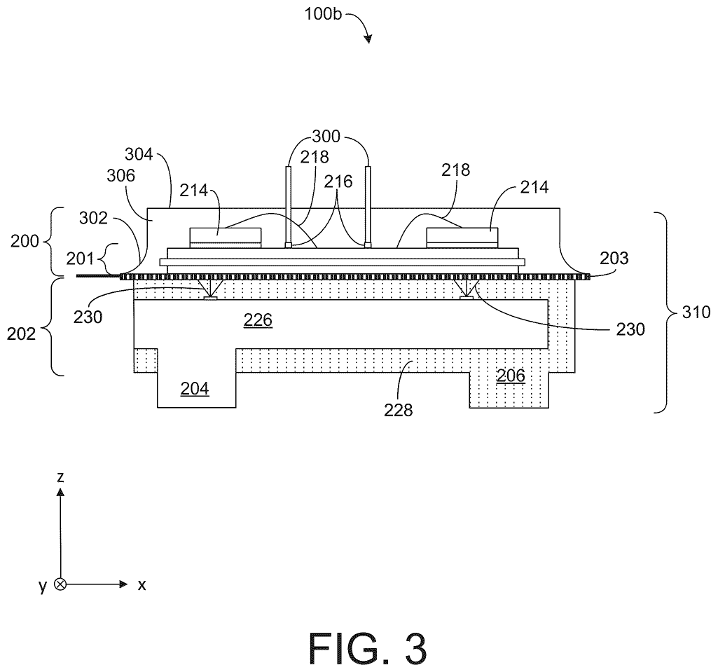

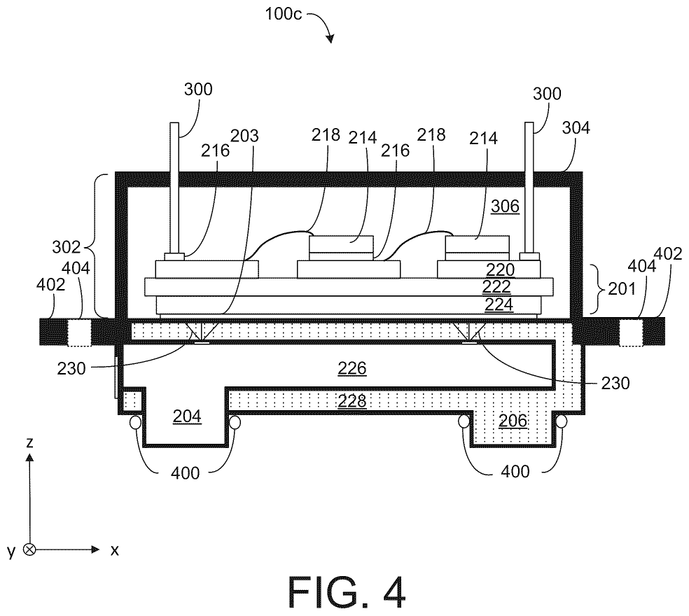

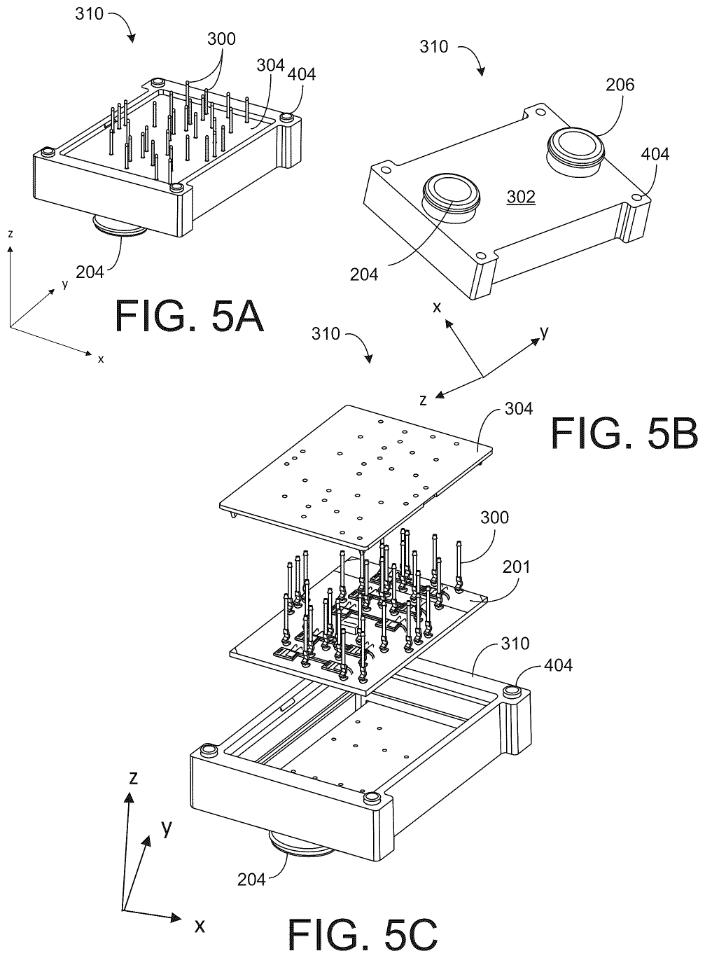

The flow 103, e.g., 103a, 103b, 103c, 103d, and 103e of cooling fluid progresses through the heat dissipation assembly 202 as indicated by a sequence of arrows and a linear path 232 connecting the arrows, as shown in FIG. 2. A constant flow of new fluid can be supplied via the cooling jacket 102. Fluid flow 103a from the cooling jacket 102 enters the inlet chamber 226 of the heat dissipation assembly 202 through the module inlet 204, and advances toward the jets 230 as flow 103b. In some implementations, the inlet chamber 226, or a portion thereof, e.g., a horizontal portion of the inlet chamber, can form a channel that pressurizes the fluid. The jets 230 then spray the pressurized cooling fluid onto an inner wall 229 of the outlet chamber 228, so that the cooling fluid impinges on a surface in thermal contact with the underside of the second conductive layer 224 of the DBM structure 201, via the conductive bonding agent 203. Spray from the jets 230 is contained within the outlet chamber 228 as flow 103c, and is directed as flow 103d toward the module outlet 206 where the cooling fluid exits the outlet chamber 228 as flow 103e. In some implementations, the structure of the inlet chamber 226 and/or the outlet chamber 228 can be formed from one or more polymer materials to reduce the weight, material cost, and cost of manufacture of the heat dissipation assembly 202 compared to previous structures that used a heavy metal, e.g., copper, baseplate as the heat dissipation assembly 202. In some implementations, the weight of the heat dissipation assembly 202 can be reduced by as much as 50% to 75% compared with the weight of a metal implementation of impingement cooling or a metal fin, e.g., “pin-fin.” In some implementations, the structure of the inlet chamber 226 and the outlet chamber 228 can be integrated into a housing, e.g., case, as described below and as shown in FIGS. 5A-5C, FIG. 6, FIG. 7, and FIG. 8.

In some implementations, any number of jets 230 can be disposed along the path of the flow 103, depending on the fluid volume, and the desired fluid pressure through the jets 230. In some implementations, the jets 230 can be in the form of an aperture through which the cooling fluid enters the outlet chamber 228. In some implementations, the jets 230 can be in the form of nozzles that permit adjusting the aperture size. In some implementations, the jets 230 can automatically adjust the aperture size based on the fluid pressure. For example, when the fluid pressure in the inlet chamber 226 is high, the aperture can be made larger, to regulate, e.g., spread out, or enlarge a spray area impinging on the inner wall 229.

In some implementations, the cooling fluid can include water and ethylene glycol, in various concentrations, e.g., a 60/40 mixture having 60% ethylene glycol and 40% water, or a 60/40 mixture having 60% water and 40% ethylene glycol, or a 50/50 mixture. Other examples of cooling fluids can include a refrigerant, a lubrication oil, or a hydraulic fluid. In some implementations, during operation of the isolated power module 100, the cooling fluid can be maintained at a temperature in a range of about −40 C to about 105 C prior to flowing through the module inlet 204. As the cooling fluid passes from the module inlet 204 to the module outlet 206, the fluid temperature can rise as much as 2-8 degrees C. as it absorbs heat from the DBM. In some implementations, the flow 103 of cooling fluid can have a flow rate through the inlet chamber 226 as high as about 12 liters/minute. In some implementations, the flow 103 of cooling fluid within the outlet chamber 228 can be in a range of about 4 liters per minute to about 15 liters per minute. In some implementations the flow rate of the cooling fluid through the module outlet 206 can be monitored and the flow rate of the cooling fluid entering the module inlet 204 can be adjusted accordingly to maintain a desired volume of cooling fluid inside the heat dissipation assembly 202 and/or inside the cooling jacket 102.

In some implementations, properties of the conductive bonding agent 203 can significantly impact the effectiveness of the jet impingement cooling described above. For example, the thickness of the conductive bonding agent 203, e.g., solder, and/or the thermal conductivity of the conductive bonding agent 203 can affect heat transfer from the second conductive layer 224 to the cooling fluid contained within the outlet chamber 226. For example, in some implementations, the thickness of the conductive bonding agent 203 can be in a range of about 30 μm to about 100 μm, and the thermal conductivity of the conductive bonding agent 203 can be in a range of about 30 W/Km to about 200 W/Km. In some implementations, the isolated power module 100 has overall dimensions of about 40×40 mm² to about 250 mm×100 mm or an area in the range of about 1600 mm² to about 25,000 mm².

FIG. 3 is a cross-sectional view of a second example 100b of the isolated power module 100, in accordance with some implementations of the present disclosure. In the second example 100b, the isolated power module 100 includes the DBM structure 201 and multiple electronic components, e.g., multiple chips or semiconductor dies 214 (two shown).

The second example 100b illustrates further details of the isolated power module 100 such as one or more external connectors 300, and a polymer case 302 having a polymer lid 304 that provides protection for the isolated power module 100. In some implementations as shown in FIG. 3, the polymer case 302 can have curved sidewalls. The polymer case 302, together with the heat dissipation assembly 202, form an isolated module case 310 around the outside of the isolated power module 100b. In some implementations, the polymer case 302 and the polymer lid 304 can be injection molded parts. In some implementations, the polymer case 302 and the polymer lid 304 can be fused using a hot plate, or a laser welding process. The DBM assembly 200 can be attached to the polymer case 302 and the polymer lid 304 using a sealing adhesive.

In some implementations, the polymer case 302 can contain an encapsulant 306. In some implementations, the encapsulant 306 can include a molding material e.g., a molding compound. For example, the molding compound can include a polymer material e.g., an epoxy molding compound (EMC), or a gel, polymer, or other molding material that serves to seal and protect the various components of the isolated power module 100, e.g., by surrounding, for example, semiconductor dies 214 that are components of the isolated power module 100. Encapsulation can be accomplished by, for example, a process of injection molding or a process of transfer molding.

In some implementations, the encapsulant 306 can expose the DBM structure 201 through openings in the encapsulant 306 and/or the conductive bonding agent 203 (not shown). For example, in some implementations, the DBM structure 201 can be disposed in an opening in the encapsulant 306 and the conductive bonding agent 203 so that a portion of the second conductive layer 224 is exposed on the bottom of the isolated power module 100. FIG. 3. In some implementations, the DBM structure 202 can be disposed in an opening in the encapsulant 212 so that the first conductive layer 220, serving as the DA, is exposed on the top side of the isolated power module 100.

In some implementations, one or more of the external connectors 300 can be a busbar connection, e.g., a solid metal bar suitable for high current power distribution. The external connectors 300 can be attached to the DBM structure 201 by the same bonding agent 216 that is used to attach the semiconductor dies 214 to the DBM structure 201. The external connectors 300 extend through the polymer lid 304 to connect to outside components such as a power source, a ground, or other high power modules. In some implementations, the external connectors 300 can replace a conventional lead frame.

Similar to the first example 100a, each of the semiconductor dies 214 in the second example 100b can be attached to, e.g., mounted on, or coupled to, a top surface of the DBM structure 201 by a bonding agent 216, e.g., an epoxy, a solder, a silver (Ag) sintering material, and/or an adhesive. In some implementations that include multiple semiconductor dies 214, different semiconductor dies 214 can be coupled to the DBM structure 201 by different bonding agents 216. For example, in some implementations that include multiple semiconductor dies 214, a first chip assembly, e.g., an IGBT, can be attached to the non-conductive layer 222 by a first bonding agent 216, e.g., solder, while a second semiconductor die 214, e.g., a controller, is attached to the non-conductive layer 222 by a second bonding agent 216, e.g., polyimide tape.

Similar to the first example 100a, the semiconductor dies 214 in the second example 100b can be fabricated on various types of semiconductor substrates as described above. In some implementations that include multiple semiconductor dies 214, different semiconductor dies 214 can be fabricated on different substrates. For example, an IGBT semiconductor die 214 can be fabricated on a silicon substrate while a controller semiconductor die 214 can be fabricated on a SiC substrate. In some implementations, multiple semiconductor dies 214 can be fabricated on a common (same) substrate.

In the second example 100b, the conductive bonding agent 203 may extend laterally outward to cover the bottom of the polymer case 302. In some implementations, the polymer case 302 can be wider than the heat dissipation assembly 202 so that the underside of the polymer case 302 and the conductive bonding agent 203 may overhang the heat dissipation assembly 202.

FIG. 4 is a cross-sectional view of a third example 100c of the isolated power module 100, in accordance with some implementations of the present disclosure. In the third example 100c, similar to the second example 100b, the isolated power module 100 includes the DBM structure 201 and multiple electronic components, e.g., multiple chips or semiconductor dies 214 (two shown) as well as multiple external connectors 300 (two shown) and the polymer case 302. The third example 100b illustrates a different shape for the polymer case 302, having vertical sidewalls.

The third example 100b further illustrates details of the isolated power module 100 such as O-ring seals 400 and mounting brackets 402 having mounting holes 404. In some implementations, the module inlet 204 and the module outlet 206 can be sealed against leaks with O-ring seals 400 at a junction where the inlet 104 and the outlet 106 meet the outlet chamber 228. The isolated power module 100c can be mounted to a chassis, e.g., a vehicle chassis or an equipment chassis using the mounting brackets 402 by securing hardware in and around the mounting holes 404.

FIGS. 5A, 5B, and 5C show three different views of the isolated module case 310, in accordance with some implementations of the present disclosure. In some implementations, the interior of the isolated module case 310 can incorporate the module inlet 204, the module outlet 206, and the jets 230 to form an integrated jet impingement cooler.

FIG. 5A is a top perspective view of the isolated module case 310, in accordance with some implementations of the present disclosure. FIG. 5A shows the heat dissipation assembly 202, the polymer lid 304, and multiple external connectors 300 (20 shown). In some implementations, the polymer lid 304 can be secured to the cooling jacket 102 by corner posts 500 (4 shown) that may accommodate one or more sets of mounting screws.

FIG. 5B is a bottom perspective view of the isolated module case 310, in accordance with some implementations of the present disclosure. FIG. 5B shows protrusions of the module inlet 204 and the module outlet 206, extending out from a bottom surface of the isolated power module 100.

FIG. 5C is an exploded view of the isolated module case 310, in accordance with some implementations of the present disclosure. FIG. 5C illustrates how the isolated power module 100, including the DBM structure 201 and the external connectors 300, fits into the isolated module case 310, and is secured by the polymer lid 304.

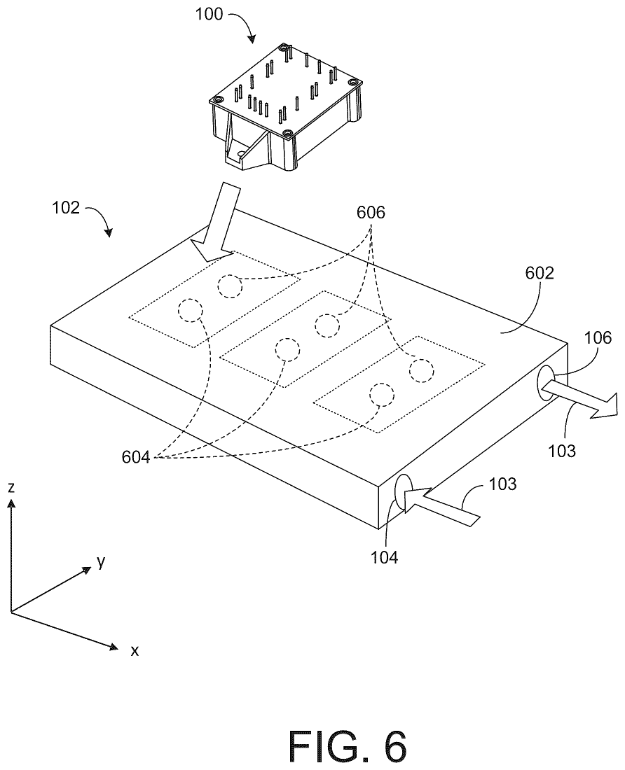

FIG. 6 is a top perspective view of an interface between the cooling jacket 102 and isolated power modules 100, in accordance with some implementations of the present disclosure. FIG. 6 shows how the isolated power modules 100 (e.g., examples 100a, 100b, 100c and so forth) attach to the cooling jacket 102. The cooling jacket 102 as depicted in the example shown in FIG. 6 can accommodate three isolated power modules 100. In some implementations, a top surface 602 of the cooling jacket 102 can be configured with openings, e.g., slots 604 (3 shown) on a same side of the cooling jacket 102 as the inlet 104 and slots 606 (3 shown) on a same side of the cooling jacket 102 as the outlet 106. The slots 604 are designed to interface with, e.g., align with, and receive placement of, module inlets 204 on bottom surfaces of the isolated power modules 100 as shown in FIG. 5B. Similarly, the slots 606 are designed to interface with, e.g., align with, and receive placement of module outlets 206 on bottom surfaces of the isolated power modules 100 as shown in FIG. 5B. The slots 604 and/or the slots 606 can have shapes other than the circular shapes depicted in FIG. 6, for example, oval, square, or any other shape that will hold the isolated power modules 100 in place.

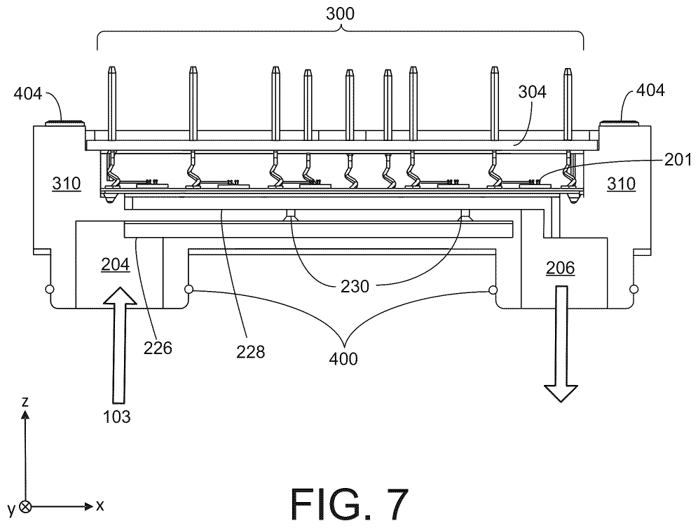

FIG. 7 is a cross-sectional view of the isolated module case 310, in accordance with some implementations of the present disclosure. FIG. 7 shows that the isolated module case 310 is an integral part of the cooling structure of the isolated power module 100. For example, the module inlet 204 and the module outlet 206 can be formed in the isolated module case 310, Furthermore, the inlet chamber 226, the outlet chamber 228, and the jets 230 can also be formed in the isolated module case 310. The DBM structure 201 and the external connectors 300 can then be installed in the isolated module case 310. The polymer lid 304 can then be used to support the external connectors 300, which extend upward in the z-direction, and pass through holes in the polymer lid 304.

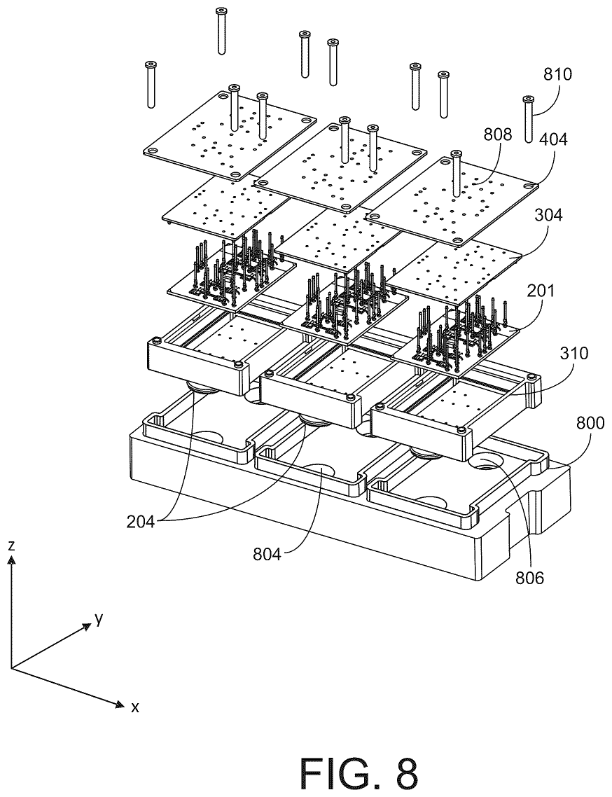

FIG. 8 is an exploded view of a manifold 800 for use with isolated power modules 100, in accordance with some implementations of the present disclosure. The manifold 800 provides a structural base and a coolant interface for the isolated power modules 100 (three shown). In some implementations, the manifold 800 can be used as an alternative to the cooling jacket 102. Like the cooling jacket 102, the manifold 800 can be made of aluminum or a polymer, and the manifold 800 is configured to channel a cooling fluid into the heat dissipation assembly 202 of the isolated power module 100. A manifold inlet 804 can be aligned so as to interface with the module inlet 204 and direct cooling fluid upward, in the positive z-direction, toward the DBM structure 201. Likewise, a manifold outlet 806 can be aligned so as to interface with the module outlet 206, to direct a flow of cooling fluid downward, in the-z direction, away from the DBM structure 201. A first set of mounting screws (not shown) can be used to attach the isolated power module 100 to the manifold 800.

Above the polymer lid 304, a printed circuit board assembly (PCBA) 808 can be added to receive a second set of mounting screws, e.g., mounting screws 810 into screw holes 404 in the isolated module case 310. The mounting screws 810 thus attach the PCBA 808 to the isolated module case 310.

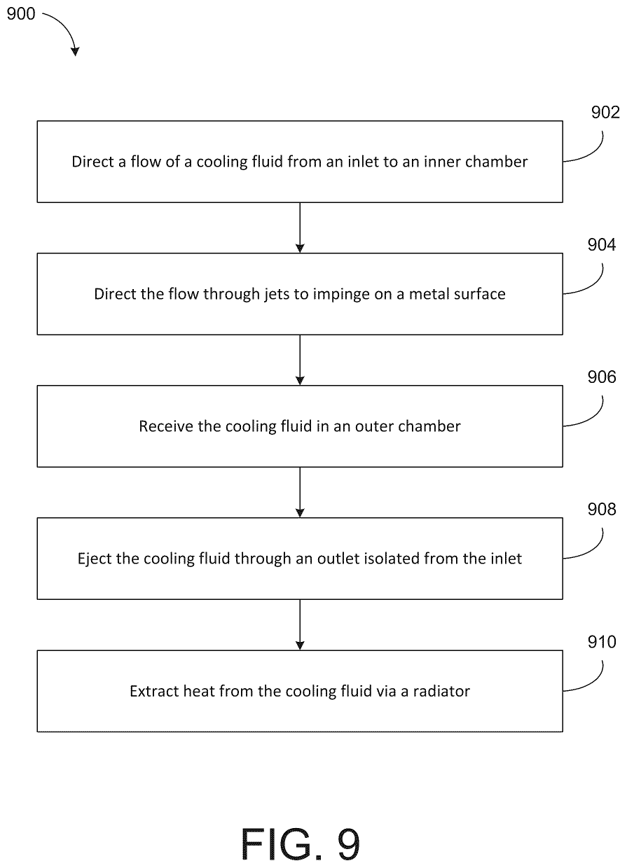

FIG. 9 is a flow chart illustrating a method 900 for cooling a power module, e.g., the isolated power module 100, in accordance with some implementations of the present disclosure. Operations 902-910 of the method 400 can be carried out, according to some implementations as described below, with reference to FIGS. 1-10 above. Operations of the method 900 can be performed in a different order, or not performed, depending on specific applications. It is noted that the method 900 may not completely cool the isolated power module 100. Accordingly, it is understood that additional processes can be provided before, during, or after method 900, and that some of these additional processes may be briefly described herein.

At 902, the method 900 includes directing a flow of cooling fluid from an inlet, e.g., the inlet 104 of the cooling jacket 102, and/or the module inlet 204, to an inner chamber, e.g., the inner chamber 226, of the isolated power module 100. In some implementations, the inner chamber 226 forms a channel having dimensions that can influence the flow rate and/or pressure of the cooling fluid. The size of the channel that guides fluid flow through the inner chamber 226 is a function of the surface area of the DBM and the desired pressure differential between the inner chamber 226 and the outer chamber 228.

At 904, the method 900 includes directing the flow of the cooling fluid from the inner chamber 226 to the outer chamber 228 through apertures, e.g., through the jets 230. The jets 230 are formed in a wall of the inner chamber 226. From the inner chamber 226, the cooling fluid can be directed through the jets 230 to impinge on a metal surface of the conductive bonding agent 203 that is in thermal contact with the underside of the second conductive layer 224. In some implementations, the cooling fluid can form a pressurized spray as it flows through small openings in the jets 230. In some implementations, the pressurized spray of cooling fluid can become an aerosol, e.g., an aerosolized spray. In some implementations, a portion of the cooling fluid can be directed so as to bypass the jets 230 via a bypass valve or via bypass flow jets e.g., when a difference in fluid pressure between the module inlet 204 and the module outlet 206 exceeds a desired pressure difference.

At 906, the method 900 includes receiving the cooling fluid in an outer chamber, e.g., the outer chamber 228 of the isolated power module 100, which is isolated from the inner chamber 226 of the isolated power module 100 so that the cooling fluid will not flow back into the inner chamber 226.

At 908, the method 900 includes ejecting the cooling fluid through an outlet, e.g., the module outlet 206 of the isolated power module 100, which is isolated from the module inlet 204 of the isolated power module 100. Isolation is provided by two distinct chambers—the outer chamber 228 and the inner chamber 226, which are separate and do not allow the cooling fluid to mix between the two chambers.

At 910, the method 900 includes extracting heat from the cooling fluid via a radiator, so that hot fluid is not recirculated, e.g., re-used as the cooling fluid. Heat extraction allows use of a closed-loop system in which the fluid re-circulates, but only after the fluid attains a temperature below a cooling fluid setpoint. In some implementations, the radiator can be disposed in the cooling jacket 102.

As described above, various implementations of a semiconductor device module for use in high power applications incorporate a fluid cooling scheme designed to improve reliability and reduce cost and weight of the heat sink. Fluid can be pumped from a cooling jacket 102 through an inlet to a first reservoir, then sprayed onto a metal surface, and then captured into a second reservoir that is isolated from the first reservoir. The metal surface can be in thermal contact with a DBM structure supporting the high power chip being cooled. The inlet, outlet, reservoirs, and spray nozzles can be integrated into a module case. A manifold can be substituted for the cooling jacket.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes, and equivalents will now occur to those skilled in the art. For instance, features illustrated with respect to one implementation can, where appropriate, also be included in other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. A module, comprising:
a direct-bonded metal structure including a first conductive layer, a second conductive layer, and a non-conductive layer disposed between the first conductive layer and second conductive layer;
a semiconductor die coupled to the first conductive layer of the direct-bonded metal structure; and
a cooling unit coupled to the second conductive layer of the direct-bonded metal structure, the cooling unit including a fluid path such that a cooling fluid, when flowing through the fluid path, absorbs heat from at least a portion of the direct-bonded metal structure.

2. The module of claim 1, wherein the cooling fluid impinges on a surface in thermal contact with the direct-bonded metal structure.

3. The module of claim 1, wherein the direct-bonded metal structure includes a dielectric layer disposed between the first conductive layer and the second conductive layer, and the cooling fluid impinges on a surface in thermal contact with the second conductive layer.

4. The module of claim 1, wherein the cooling unit includes a polymer-based material.

5. The module of claim 1, wherein the cooling unit includes an inlet chamber and an outlet chamber that are separate from one another, and connected by cooling impingement jets.

6. The module of claim 5, wherein the cooling unit is configured to direct flow of a cooling fluid from a module inlet, through a jet formed therein, toward the direct-bonded metal structure, and then away from the direct-bonded metal structure via the outlet chamber.

7. The module of claim 6, wherein some of the cooling fluid that has passed through the jet is expelled from the cooling unit through a module outlet of the outlet chamber.

8. The module of claim 7, wherein a temperature of the cooling fluid rises by up to between 2 degrees Celsius and 8 degrees Celsius while passing between the module inlet and the module outlet.

9. The module of claim 7, wherein the module inlet and the module outlet include O-ring seals.

10. The module of claim 1, further comprising a polymer lid over the semiconductor die.

11. The module of claim 10, further comprising an epoxy between the polymer lid and the semiconductor die.

12. The module of claim 1, wherein the cooling fluid includes ethylene glycol.

13. An apparatus, comprising:
an inner chamber having an inlet;
an outer chamber having an outlet, the outer chamber at least partially surrounding the inner chamber; and
a channel formed in the inner chamber to direct a flow of a cooling fluid toward the outer chamber.

14. The apparatus of claim 13, wherein the inner chamber and the outer chamber are formed from a polymer material by 3D printing.

15. The apparatus of claim 13, wherein the inner chamber and the outer chamber are formed from a polymer material by injection molding.

16. The apparatus of claim 13, wherein the channel pressurizes the cooling fluid to form an aerosol.

17. The apparatus of claim 13, wherein the inlet is disposed below the inner chamber and the outlet is disposed below the outer chamber.

18. A method, comprising:
directing a flow of a cooling fluid from an inlet to an inner chamber formed within a substrate supporting a semiconductor die such that heat is absorbed by the cooling fluid;
directing the flow from the inner chamber through a plurality of openings to form a pressurized spray, causing the cooling fluid to impinge on a metal surface in thermal contact with a direct-bonded metal structure;
receiving the cooling fluid in an outer chamber formed within the substrate; and
ejecting the cooling fluid from the outer chamber through an outlet that is isolated from the inlet.

19. The method of claim 18, wherein the cooling fluid is disposed below the direct-bonded metal structure.

20. The method of claim 18, wherein the direct-bonded metal structure includes a first conductive layer, a second conductive layer, and a non-conductive layer disposed between the first conductive layer and second conductive layer.
